(19) United States
(12) Patent Application Publication
(10) Pub. No.: US 2026/0107808 A1
(43) Pub. Date: Apr. 16, 2026

(54) DECOUPLED FLOATING BONDING STAGE

(71) Applicant: ASMPT Singapore Pte. Ltd., Singapore (SG)

(72) Inventors: Kuok Hang MAK, Hong Kong (CN); Ka Shing KWAN, Singapore (SG); See Yui FUNG, Hong Kong (CN); Shing Chun MAK, Hong Kong (CN)

(21) Appl. No.: 18/915,665

(22) Filed: Oct. 15, 2024

(51) Int. Cl. H01L 23/00; G01D 5/24

(52) U.S. Cl. CPC H10W 72/011; G01D 5/24; H10W 72/071

(57) ABSTRACT

A bonding stage for positioning a bond head at a target position has a stage body on which the bond head is mounted and a linear carriage which is physically decoupled from the stage body. The stage body is drivable to move together with the linear carriage by way of electromagnetic interaction between the linear carriage and the stage body when the bond head is being moved towards the target position by the linear carriage. The stage body is also drivable to move relative to the linear carriage to position the bond head at the target position by way of the electromagnetic interaction.

### FIELD OF THE INVENTION

The invention relates to semiconductor assembly and packaging equipment, and in particular to a positioning mechanism for precisely positioning a bonding stage including a bond head.

### BACKGROUND AND PRIOR ART

In the semiconductor assembly and packaging industry, conventional planar positioning stages for equipment such as die bonders that bond semiconductor dies onto substrates are typically constructed in a stacked configuration. Included in such a stack is a linear stage that is movable along a first axis, and this linear stage is mounted and stacked onto another linear stage that is movable along a second axis perpendicular to the first axis. An example of such a stacked planar positioning stage is described in U.S. Patent Number 6,983,703 B2 entitled “Driving Means to Position a Load”.

In such a stacked stage configuration, the motion performances of the two linear axes would tend to be different as they have different inherent payloads and dynamic properties. In particular, it is challenging for stacked stages to achieve sub-micron or nanometer-level positioning accuracy when they are being driven with high acceleration.

More recently, planar movable stages that avoid the aforesaid stacked configuration have been gaining popularity in the market although they are still less common. They are capable of offering better motion performance than stacked movable stages, especially for achieving better contour motion performance. However, as a stator of the planar motor usually includes a set of coil assemblies, a travel range of a planar stage over a two-dimensional space, and thus its operational area, is typically limited.

These plate-like planar stages may not be suitable for operating at high levels of acceleration along the large travel ranges typically required in the semiconductor assembly and packaging industry, especially when high precision is also required in their motion trajectories. It would thus be beneficial to develop a bonding stage that avoids the aforesaid shortcomings of the prior art.

### SUMMARY OF THE INVENTION

It is thus an object of the invention to seek to provide a bonding stage that is capable of operating at high levels of acceleration with less vibration over a relatively large travel range to achieve more precise positioning than prior art bonding stages.

According to a first aspect of the invention, there is provided a bonding stage for positioning a bond head at a target position, the bonding stage comprising: a stage body on which the bond head is mounted; and a linear carriage which is physically decoupled from the stage body, the stage body being drivable to move together with the linear carriage by way of electromagnetic interaction between the linear carriage and the stage body when the bond head is being moved towards the target position by the linear carriage; wherein the stage body is further drivable to move relative to the linear carriage to position the bond head at the target position by way of the electromagnetic interaction.

According to a second aspect of the invention, there is provided a method for positioning a bond head mounted on a stage body on a bonding stage, the method comprising the steps of: driving the stage body to move together with a linear carriage by way of electromagnetic interaction between the linear carriage and the stage body when the bond head is being moved towards a target position by the linear carriage; and thereafter driving the stage body to move relative to the linear carriage by way of the electromagnetic interaction to position the bond head at the target position; wherein the linear carriage which is physically decoupled from the stage body.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

A specific example of a bonding stage in accordance with the invention will now be described with reference to the accompanying drawings, in which:

FIG. 1 is an isometric view of a bonding stage in accordance with the preferred embodiment of the invention;

FIG. 2 is a front view of the bonding stage looking from direction A in FIG. 1;

FIG. 3 is a plan view of the bonding stage looking from direction B in FIG. 1;

FIG. 4 is an isometric view of the bonding stage of FIG. 1 wherein a floating stage body and bond head have been removed to show a long-stroke aspect of the bonding stage;

FIG. 5 is a cross-sectional view of the bonding stage looking along line C-C in FIG. 3;

FIG. 6 is an isometric view of the floating stage body including the bond head;

FIG. 7 is a plan view of the floating stage body of FIG. 6; and

FIG. 8 is an isometric view of the bonding stage wherein a short-stroke aspect of the bonding stage is more clearly illustrated.

### DETAILED DESCRIPTION OF THE PREFERRED EMBODIMENTS OF THE INVENTION

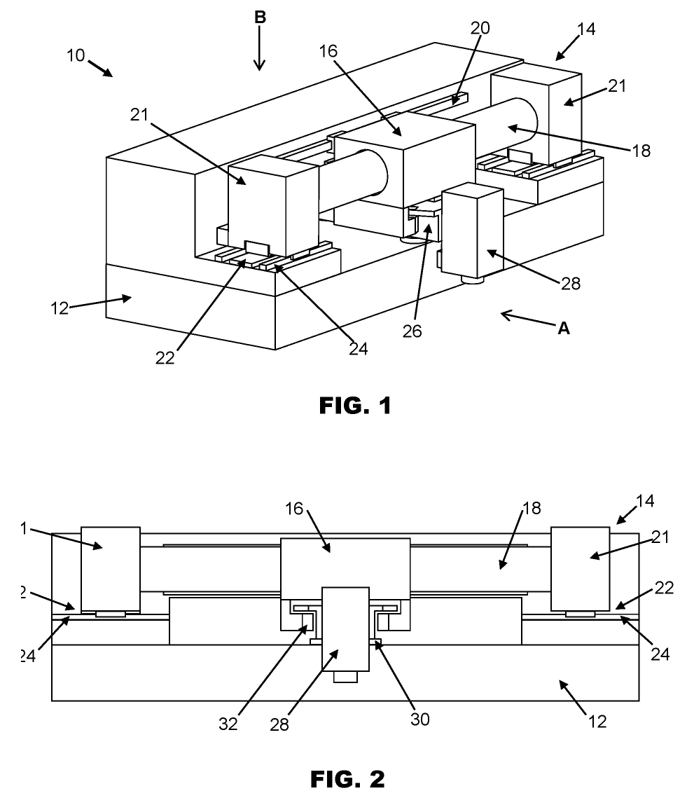

FIG. 1 is an isometric view of a bonding stage 10 in accordance with the preferred embodiment of the invention. The bonding stage 10 generally has a base 12 on which a linear motor 14 is mounted, the linear motor 14 being configured to drive a linear carriage 16 to slide along a shaft 18. Linear motion of the linear carriage 16 is guided and maintained by a carriage linear guideway 20. The linear motor 14 may include a coil assembly mounted on the linear carriage 16 and a magnet mounted on the shaft 18 for moving the linear carriage 16 by electromagnetic interaction, although it would be appreciated the linear carriage 16 may contain a magnet and the shaft 18 may contain a coil assembly instead.

A pair of end mountings 21 may be located at opposite ends of the shaft 18 for supporting the shaft 18, and each end mounting 21 is installed on a balancing mass linear motor 22. The balancing mass linear motors 22 serve to adjust and correct the positions of the end mountings 21 in directions parallel to the motion directions of the linear carriage 16. Each end mounting 21 is guided to move parallel to the linear carriage 16 by an end mounting linear guideway 24.

The end mountings 21 of the balancing mass linear motors 22 are by design free to move in the linear travelling directions of the linear carriage 16 in order to allow a motor reaction force to turn into a motion momentum of the end mountings 21 so that the reaction force is not transferred to the base 12 and the rest of the bonding machine. Thus, the end mountings 21 operate as balancing masses at both ends of the shaft 18. With this mechanical arrangement, the transmissibility of vibrations in the positioning stage is minimized and the bonding machine is configured not to be excited by motor reaction forces during positioning of the bonding stage 10.

A stage body, which may be in the form of a floating stage body 26, is operatively connected to the linear carriage 16 and it is movable together with the linear carriage 16 when the linear carriage 16 is driven to slide along the shaft 18 by the linear motor 14. The floating stage body is supported on the base 12. A bond head 28 that has a collet or other gripping mechanism is mounted on the floating stage body 26 for picking up an electronic device (such as a semiconductor chip) from one location and placing or bonding it at another location. The linear carriage 16 serves to drive the bond head 28 to move along a linear motion axis between the said pick-up and placement positions. The floating stage body 26, in conjunction with the bond head 28, provides rotational motion in multiple degrees of freedom to adjust the orientation of the bond head 28 and an electronic device being carried by the bond head 28.

FIG. 2 is a front view of the bonding stage 10 looking from direction A in FIG. 1. This view shows air bearing pads 30 mounted under the floating stage body 26 for creating an air gap between the floating stage body 26 and the base 12, so that the floating stage body 26 is capable of achieving smooth and frictionless sliding along a top surface of the base 12. In addition, a planar motor including a planar motor coil assembly 32 incorporated in the linear carriage 16 is operative to drive the floating stage body 26 to move relative to the linear carriage 16 after the linear carriage 16 has positioned the floating stage body 26 carrying the bond head 28 to an approximate location where the bond head 28 is to pick up or to place an electronic device.

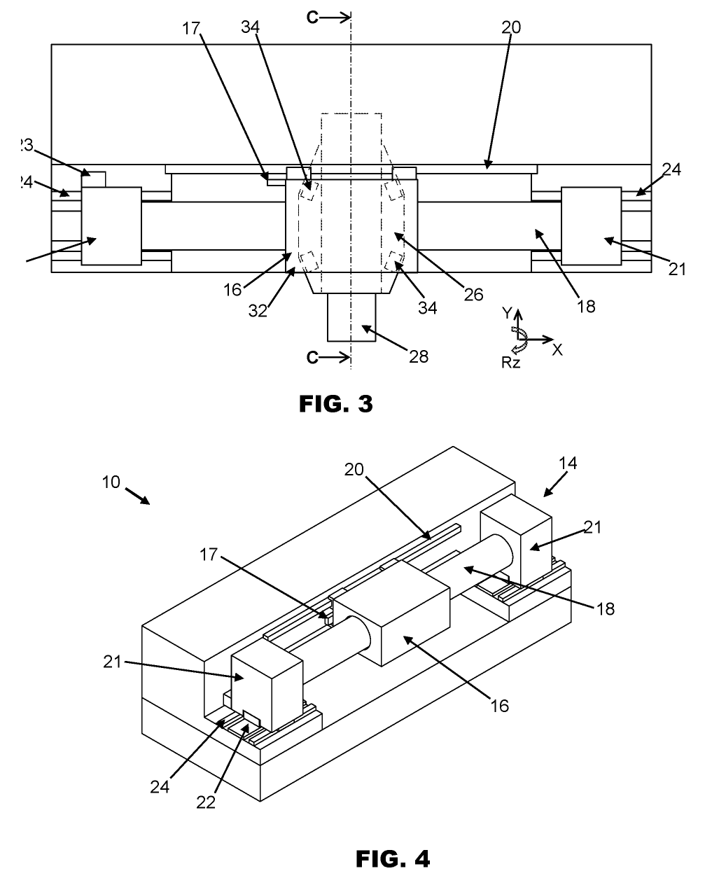

FIG. 3 is a plan view of the bonding stage 10 looking from direction B in FIG. 1. A top view of the motion directions of the linear carriage 16 is shown, wherein the linear carriage 16 is guided to move linearly along the shaft 18 while being guided by the carriage linear guideway 20. A carriage position sensor 17 mounted on the linear carriage 16 constantly monitors a position of the linear carriage 16 along the carriage linear guideway 20, while a displacement sensor 23 which is mounted on one of the end mountings 21 monitors a position of the end mounting 21 along the end mounting linear guideway 24.

A plan view of the floating stage body 26 is also shown relative to the linear carriage 16. While the floating stage body 26 is configured to move together with the linear carriage 16 by electromagnetic interaction between the planar motor coil assembly 32 and multiple planar motor magnets 34 incorporated in the floating stage body 26 when the bond head 28 is being moved towards a target position by the linear carriage 16, the floating stage body 26 is also drivable by the said electromagnetic interaction to move relative to the linear carriage 16 for fine positioning of the bond head 28 at the target position. Such fine positioning can be conducted at a nanometer scale on a plane parallel to the top surface of the base 12, in both linear (X, Y) as well as rotary (Rz) directions.

FIG. 4 is an isometric view of the bonding stage 10 of FIG. 1 wherein the floating stage body 26 and bond head 28 have been removed to show a long-stroke aspect of the bonding stage 10. The long-stroke aspect of the bonding stage 10 refers to the positioning of the linear carriage 16, floating stage body 26 and bond head 28 over a longer distance with high acceleration to an approximate location where the bond head 28 is required. After such long-stroke positioning, short-stroke or fine positioning of the bond head 28 is conducted with nanometer-level accuracy.

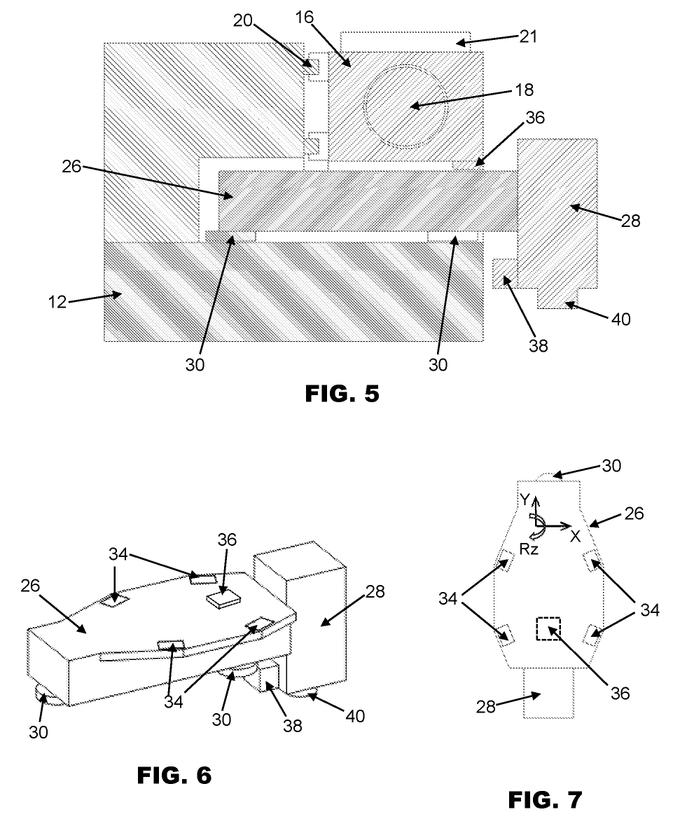

FIG. 5 is a cross-sectional view of the bonding stage 10 looking along line C-C in FIG. 3. The shaft 18 is mounted on the end mountings 21 and the linear carriage 16 is slidably driven on the shaft 18 while it is being guided by the carriage linear guideway 20. The floating stage body 26 is movable together with the linear carriage 16, and the floating stage body 26 is slidable on the base 12 in a frictionless manner since it is spaced from the base 12 by air bearings formed by the air bearing pads 30. A local position sensor set 36 is mounted on the linear carriage 16 between the linear carriage 16 and the floating stage body 26 for determining a position of the floating stage body 26 relative to the linear carriage 16. Additionally, a global position sensor set 38 is mounted on the bond head 28 for determining a global position of the bond head 28 relative to the base 12. The local position sensor set 36 may comprise an encoder sensor that is movable relative to an encoder scale, while the global position sensor set 38 may comprise a set of capacitive sensors and a set of encoder sensors that are movable relative to a reference plate (such as a metallic plate) and one or more encoder scales fixedly attached with respect to the base 12 for extremely accurate position measurement. A collet 40 is further illustrated as being mounted at a bottom of the bond head 28 for picking up and placing electronic devices.

FIG. 6 is an isometric view of the floating stage body 26 including the bond head 10. The floating stage body 26 includes a plurality of planar motor magnets 34 on a top surface of the floating stage body 26 located at opposite edges thereof for electromagnetic interaction with the planar motor coil assembly 32 incorporated on the linear carriage 16. In the illustrated embodiment, there are four separate planar motor magnets 34 that are oriented at different predetermined angles relative to one another so that a plurality of motor forces arising from the electromagnetic interaction act in different angular directions relative to one another. This enables the floating stage body 26 to be driven on a plane that is parallel to a top surface of the base 12 in X-Y linear directions as well as in rotary directions in multiple degrees of freedom. The bond head 28 that is carried on the floating stage body 26 is thus positioned by the fine positioning of the floating stage body 26. Also illustrated in dotted lines is the local position sensor set 36 that is attached to the linear carriage 16.

FIG. 7 is a plan view of the floating stage body 26 of FIG. 6. Motion directions of the floating stage body 26 in the X, Y and rotary directions (Rz) while it is being driven by electromagnetic interaction along an XY plane are shown. The four planar motor magnets 34 that form the planar motor consist of four iron core motors to drive the floating stage body 26 to move. These iron core motors are located and aligned in a manner where the motor forces act in different angular directions relative to one another on the X-Y plane. The electromagnetic forces generated by the planar motor are used to control the planar movements of the floating stage body 26, although there is no physical connection to the linear carriage 16.

To obtain maximum air bearing stiffness of the bearing pads 30, the bearing pads 30 are adequately preloaded by an intrinsic magnetic attraction force between the planar motor coil assembly 32 and the planar motor magnets 34 of the planar motor. In operation, the local displacement sensor set 36 measures relative positions between the floating stage body 26 and the linear carriage 16 when the linear carriage 16 moves the floating stage body 26 to a target position. Such relative position should be minimized to as close to zero as possible during this time so that the floating stage body 26 can travel synchronously with the linear carriage 16. Accordingly, the local position sensor set 36 is operative to synchronize a position of the floating stage body 26 such that it corresponds to a position of the linear carriage 16 when the floating stage body 26 is being driven to move together with the linear carriage 16 by electromagnetic interaction.

Once the floating stage body 26 has been brought to a target position of the bond head 28, the local displacement sensor set 36 is no longer needed and synchronization between the floating stage body 26 and the linear carriage 16 is suspended. The floating stage body 26 will then adjust a position of the bond head 28 according to measurements made by the global position sensor set 38 of the location of the bond head with respect to the base 12.

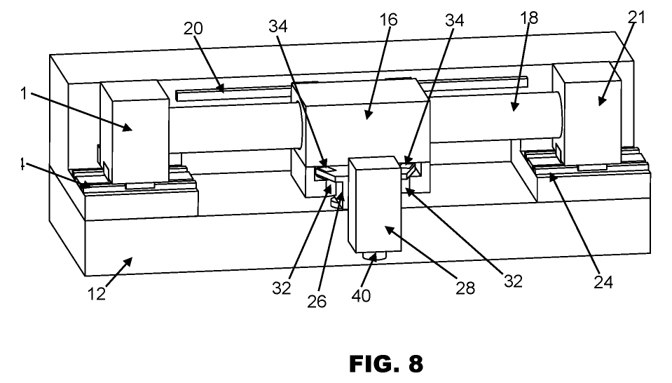

FIG. 8 is an isometric view of the bonding stage wherein a short-stroke aspect of the bonding stage 10 is more clearly illustrated. Short-stroke positioning of the bond head 28 refers to the fine positioning of the bond head 28 over a limited area with nanometer-level accuracy. As previously mentioned, after long-stroke positioning of the bond head 28 by the linear motor 14 over a larger distance with a higher acceleration along substantially a whole width of the base 12 to an approximate location of the target position, short-stroke positioning of the bond head 28 is deployed to finely position the bond head 28 over a shorter distance than the linear carriage 16 with a higher accuracy than the linear carriage 16 to the target position.

The floating stage body 26 is only electromagnetically coupled to the linear carriage 16 by the electromagnetic force between the planar motor coil assembly 32 and the planar motor magnets 34. Such coupling is ensured by motion control implemented based on their relative positions measured by the local displacement sensor set 36. Once the linear carriage 16 has brought the floating stage body 26 to a desired position of the bond head 28 (such as a pick-up or bonding position), electromagnetic forces are used to accurately position the bond head 28 relative to the base 12 by relying on its position that is measured by the global position sensor set 38. In particular, the linear carriage 16 carries a planar motor coil assembly 32 while the floating stage body 26 carries the planar motor magnets 34, and there is a gap between the planar motor magnets 34 and the planar motor coil assembly 32. The said gap between the planar motor magnets 34 and the planar motor coil assembly 32 ensures that the floating stage body 26 is physically decoupled from the linear carriage 16, while the air bearing pads 30 forming the air bearing forms a gap between the floating stage body 26 and the base 12 to ensure frictionless travel of the floating stage body 26 carrying the bond head 28. These features enable nanometer-level positioning accuracy to be attained.

It should be appreciated that the positioning stage 10 as described in the preferred embodiment of the invention offers outstanding planar motion performance which is capable of operating at high levels of acceleration. The decoupling of the floating stage body 26 from the linear carriage 16 performs a key role of allowing the floating stage body 26 to position the bond head 28 with high accuracy without being affected by dynamical disturbance arising from the movement of the linear carriage 16.

With such a mechanical configuration together with the aforementioned mode of operation, vibration transmissibility from the positioning stage to the bonding machine is very low. Due to the rest of bonding machine being vibrationally isolated from the positioning stage 10, the bonding machine itself is less likely to be excited by the movement of the positioning stage. It remains a steady and mechanical noise-free platform not only for the positioning stage, but also for all other mechanical, electrical and optical modules mounted on the bonding machine.

With the aid of the linear carriage 16, the floating stage body 26 can be finely positioned within an applicable work area on the base 12 to offer excellent motion performance without having to extend the travel range of the floating stage body 26 as such. A travel range of the floating stage body 26 can therefore be extended by the linear carriage 16 without unnecessarily deteriorating the motion performance or reducing the maximum acceleration available for to the floating stage body 26 when conducting fine positioning.

The invention described herein is susceptible to variations, modifications and/or additions other than those specifically described and it is to be understood that the invention includes all such variations, modifications and/or additions which fall within the spirit and scope of the above description.

1. A bonding stage for positioning a bond head at a target position, the bonding stage comprising:
a stage body on which the bond head is mounted; and
a linear carriage which is physically decoupled from the stage body, the stage body being drivable to move together with the linear carriage by way of electromagnetic interaction between the linear carriage and the stage body when the bond head is being moved towards the target position by the linear carriage;
wherein the stage body is further drivable to move relative to the linear carriage to position the bond head at the target position by way of the electromagnetic interaction.

2. The bonding stage as claimed in claim 1, further comprising a shaft on which the linear carriage is configured to slide and a linear motor to drive the linear carriage to move along the shaft.

3. The bonding stage as claimed in claim 2, wherein the linear motor comprises a coil assembly mounted on the linear carriage and a magnet mounted on the shaft.

4. The bonding stage as claimed in claim 2, further comprising a pair of end mountings located at opposite ends of the shaft for supporting the shaft, each end mounting being installed on a balancing mass linear motor which is operative to adjust and correct positions of the end mountings in directions parallel to the movement of the linear carriage, whereby to cause a motor reaction force to turn into a motion momentum of the end mountings.

5. The bonding stage as claimed in claim 4, further comprising a displacement sensor mounted at each end mounting for monitoring a position of the end mounting relative to an end mounting linear guideway on which the end mounting is mounted.

6. The bonding stage as claimed in claim 1, further comprising a planar motor coil assembly incorporated in the linear carriage and planar motor magnets incorporated in the stage body for generating the electromagnetic interaction between the linear carriage and the stage body.

7. The bonding stage as claimed in claim 6, including a gap between the stage body and the linear carriage to physically decouple the stage body from the linear carriage.

8. The bonding stage as claimed in claim 6, wherein the planar motor magnets are oriented at different angles relative to one another, so that a plurality of motor forces arising from the electromagnetic interaction act in different angular directions relative to one another.

9. The bonding stage as claimed in claim 6, further comprising air bearing pads mounted under the stage body for creating an air bearing between the stage body and a base on which the stage body is supported.

10. The bonding stage as claimed in claim 9, wherein the air bearing pads are preloaded by an intrinsic magnetic attraction force between the planar motor magnets and the planar motor coil assembly.

11. The bonding stage as claimed in claim 1, further comprising a local position sensor set mounted between the linear carriage and the stage body for determining a position of the stage body relative to the linear carriage.

12. The bonding stage as claimed in claim 11, wherein the local position sensor set comprises an encoder sensor that is movable relative to an encoder scale.

13. The bonding stage as claimed in claim 11, wherein the local position sensor is operative to synchronize a position of the stage body such that it corresponds to a position of the linear carriage when the stage body is being driven to move together with the linear carriage.

14. The bonding stage as claimed in claim 1, further comprising a global positioning sensor set mounted on the bond head for determining a position of the bond head relative to a base on which the stage body is supported.

15. The bonding stage as claimed in claim 14, wherein the global position sensor set comprises a set of capacitive sensors and a set of encoder sensors that are movable together relative to a reference plate and an encoder scale fixedly attached with respect to the base.

16. The bonding stage as claimed in claim 1, wherein the linear carriage is operative to drive the bond head to move over a larger distance with a higher acceleration to an approximate location of the target position, and the stage body is operative to position the bond head over a shorter distance than the linear carriage but with a higher accuracy than the linear carriage to the target position.

17. The bonding stage as claimed in claim 1, wherein the stage body is drivable to move relative to the linear carriage on a plane that is parallel to a top surface of a base on which the stage body is supported in linear directions as well as rotary directions in multiple degrees of freedom.

18. A method for positioning a bond head mounted on a stage body on a bonding stage, the method comprising the steps of:
driving the stage body to move together with a linear carriage by way of electromagnetic interaction between the linear carriage and the stage body when the bond head is being moved towards a target position by the linear carriage; and thereafter
driving the stage body to move relative to the linear carriage by way of the electromagnetic interaction to position the bond head at the target position;
wherein the linear carriage which is physically decoupled from the stage body.
